(19) United States
(12) Patent Application Publication
(10) Pub. No.: US 2017/0009342 A1
(43) Pub. Date: Jan. 12, 2017

(54) PEDESTAL AND METHOD FOR CONTROLLING THE SAME, TRAY, AND PROCESS CHAMBER

(71) Applicant: TSINGHUA UNIVERSITY, Beijing (CN)

(72) Inventors: DONG XIANG, Beijing (CN); HUANXIONG XIA, Beijing (CN); WANG YANG, Beijing (CN); PENG MOU, Beijing (CN); HAN ZHANG, Beijing (CN); WEI WANG, Beijing (CN); XUEPING LIU, Beijing (CN)

(21) Appl. No.: 15/113,418

(22) PCT Filed: Apr. 3, 2014
(86) PCT No.: PCT/CN2014/074706

§ 371 Date: Jul. 21, 2016

(30) Foreign Application Priority Data
Jan. 22, 2014 (CN) 201410029395.8

(51) Int. Cl. C23C 16/458; C23C 16/46; C23C 16/505; C23C 16/52

(52) U.S. Cl. CPC C23C 16/4586; C23C 16/52; C23C 16/463; C23C 16/505

(57) ABSTRACT

A pedestal and a method for controlling the same, a tray, and a process chamber are provided. The pedestal comprises: a barrier (12), defining a plurality of areas, in which the plurality of areas are electrically insulated and thermally insulated from each other; a plurality of subbases (11), disposed in the plurality of areas respectively; and a control device, configured for controlling a temperature and/or a power of each subbase (11).

### CROSS-REFERENCE TO RELATED APPLICATION

This application claims priority to and benefits of Chinese Patent Application Serial No. 201410029395.8, filed with the State Intellectual Property Office of P. R. China on Jan. 22, 2014, the entire content of which is incorporated herein by reference.

### FIELD

The present disclosure relates to a manufacturing process field, and more particularly to a pedestal, a method for controlling a pedestal, a tray, and a process chamber.

### BACKGROUND

In the multi-physics coupling process, the process factors and the process objectives generally have continuous spatial distribution characteristics respectively. In order to finely control one process objective, it is necessary to finely control the spatial distributions of the process factors corresponding to the process objective.

Currently, there are some problems: the process device for the multi-physics coupling process can generally adjust the average of the process factors, and it is impossible to finely control the spatial distributions of the process factors; also, the process device does not make good use of the fact that one process objective can be influenced by the plurality of process factors corresponding to the process objective. Therefore, when the deviations occur, the process device always adjusts the process factors directly causing the deviations or the components corresponding to the process factors, but the cost is often extremely high, or even it is impossible to achieve this adjustment.

### SUMMARY

Embodiments of the present disclosure seek to solve at least one of the problems existing in the related art to at least some extent.

A first objective of the present disclosure is to provide a pedestal, which can easily achieve the fine control on the spatial distributions of the temperature field and/or the power field.

A second objective of the present disclosure is to provide a tray.

A third objective of the present disclosure is to provide a process chamber.

A fourth objective of the present disclosure is to provide a method for controlling a pedestal in a process chamber.

According to a first aspect of the present disclosure, a pedestal is provided. The pedestal comprises: a barrier, defining a plurality of areas, in which the plurality of areas are electrically insulated and thermally insulated from each other; a plurality of subbases, disposed in the plurality of areas respectively; and a control device, configured for controlling a temperature and/or a power of each subbase.

In some embodiments, the control device comprises: a plurality of temperature control modules corresponding to the plurality of subbases respectively; and a temperature controller, connected with the plurality of temperature control modules respectively.

In some embodiments, each temperature control module comprises: a heating rod; a temperature sensor; and a cooling unit, in which the heating rod, the temperature sensor and the cooling unit are disposed within the subbase corresponding to the each temperature control module, the cooling unit is disposed below the heating rod; in which the temperature controller is connected with the heating rod, the temperature sensor and the cooling unit of the each temperature control module respectively, and the temperature controller is configured for obtaining the temperature of the subbase by the temperature sensor, heating the subbase by the heating rod, and cooling the subbase by the cooling unit.

In some embodiments, the control device comprises: a plurality of power control modules corresponding to the plurality of subbases respectively; and a power controller, connected with the plurality of power control modules respectively.

In some embodiments, each power control module comprises: an adjustable resistor and/or capacitor, connected with the subbase corresponding to the each power control module, and an impedance detection unit, connected with the adjustable resistor and/or capacitor; in which the power controller is connected with the adjustable resistor and/or capacitor and the impedance detection unit of the each power control module respectively, and the power controller is configured for obtaining the power of the subbase by the impedance detection unit and controlling the power of the subbase by the adjustable resistor and/or capacitor.

In some embodiments, each subbase has an annular shape, a round shape, a sectorial shape or a sectorial annular shape.

With the pedestal according to an embodiment of the present disclosure, the plurality of subbases are independent from each other and are electrically insulated and thermally insulated from each other, so the subbases can be controlled independently. Therefore, it is possible to easily achieve the fine control on the spatial distributions (for example, the temperature distribution, the power distribution, etc.) of various physical fields (e.g., temperature fields or electromagnetic fields).

According to a second aspect of the present disclosure, a tray is provided. The tray comprises: a barrier, defining a plurality of areas, in which the plurality of areas are electrically insulated and thermally insulated from each other; and a plurality of subbases, disposed in the plurality of areas respectively, in which the plurality of subbases are made of a medium.

In some embodiments, medium parameters of the plurality of subbases are not identical.

In some embodiments, each subbase has an annular shape, a round shape, a sectorial shape or a sectorial annular shape.

With the tray according to an embodiment of the present disclosure, the tray can be placed on the pedestal to enable the energy through the tray to have a graded distribution in the normal plane, so it is possible to achieve the fine control on the spatial distributions (for example, the temperature distribution, the power distribution, etc.) of the process factors; and the tray also has a cheap, efficient, replaceable feature.

According to a third aspect of the present disclosure, a process chamber is provided. The process chamber comprises: a chamber body; a pedestal according to the first aspect of the present disclosure, in which the pedestal is received within the chamber body; and a tray according to the second aspect of the present disclosure, in which the tray is disposed above the pedestal.

With the process chamber according to an embodiment of the present disclosure, it is possible to achieve the fine control on the spatial distributions (for example, the temperature distribution, the power distribution, etc.) of the process factors (e.g., the temperature field, the power field, etc.) by means of the pedestal and the tray. Moreover, the tray can be replaced.

According to a fourth aspect of the present disclosure, a method for controlling a pedestal in a process chamber is provided. The pedestal is the one according to the first aspect of the present disclosure, and the method comprises steps of: obtaining a current temperature and/or power of the plurality of subbases; obtaining a current temperature and/or power distribution according to the current temperature and/or power of the plurality of subbases; obtaining a temperature and/or power error distribution according to the current temperature and/or power distribution and a preset temperature and/or power distribution; obtaining temperature and/or power control quantities of the plurality of subbases according to the temperature and/or power error distribution; and adjusting the temperature and/or power of the plurality of subbases according to the temperature and/or power control quantities until the temperature and/or power error distribution is within a preset range.

According to a fifth aspect of the present disclosure, a computer readable storage medium is provided. The computer readable storage medium comprises a computer program for executing the method for controlling a pedestal according to the first aspect of the present disclosure in a process chamber when running on a computer.

The above summary of the present disclosure is not intended to describe each disclosed embodiment or every implementation of the present disclosure. The Figures and the detailed descriptions which follow more particularly exemplify illustrative embodiments.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the drawings, in which:

FIG. 1 is a schematic top view of a pedestal according to an embodiment of the present disclosure;

FIG. 2 is a sectional view of the pedestal along line A-A in FIG. 1;

FIG. 3(a) is a schematic top view of a pedestal according to an embodiment of the present disclosure;

FIG. 3(b) is a schematic top view of a pedestal according to an embodiment of the present disclosure;

FIG. 3(c) is a schematic top view of a pedestal according to an embodiment of the present disclosure;

FIG. 4 is a schematic top view of a pedestal according to another embodiment of the present disclosure;

FIG. 5 is a sectional view of the pedestal along line A-A in FIG. 4;

FIG. 6 is a sectional view of a pedestal according to an embodiment of the present disclosure;

FIG. 7 is a schematic diagram of a process chamber for a PECVD process according to an embodiment of the present disclosure;

FIG. 8 is a schematic sectional view of a tray according to an embodiment of the present disclosure;

FIG. 9 is a flow chart of a method for controlling a pedestal in a process chamber according to an embodiment of the present disclosure; and

FIG. 10 is a flow chart of a method for manufacturing a tray in a process chamber according to an embodiment of the present disclosure.

### DETAILED DESCRIPTION

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

In addition, terms such as “first” and “second” are used herein for purposes of description and are not intended to indicate or imply relative importance or significance. Thus, the feature defined with “first” and “second” may comprise one or more this feature. In the description of the present disclosure, “a plurality of” means two or more than two, unless specified otherwise.

In the description of the present disclosure, it should be understood that, unless specified or limited otherwise, the terms “mounted,” “connected,” and “coupled” and variations thereof are used broadly and encompass such as mechanical or electrical mountings, connections and couplings, also can be inner mountings, connections and couplings of two components, and further can be direct and indirect mountings, connections, and couplings, which can be understood by those skilled in the art according to the detail embodiment of the present disclosure.

In the description of the present disclosure, a structure in which a first feature is “on” a second feature may include an embodiment in which the first feature directly contacts the second feature, and may also include an embodiment in which an additional feature is formed between the first feature and the second feature so that the first feature does not directly contact the second feature, unless specified otherwise. Furthermore, a first feature “on,” “above,” or “on top of” a second feature may include an embodiment in which the first feature is right “on,” “above,” or “on top of” the second feature, and may also include an embodiment in which the first feature is not right “on,” “above,” or “on top of” the second feature, or just means that the first feature is at a height higher than that of the second feature. While a first feature “beneath,” “below,” or “on bottom of” a second feature may include an embodiment in which the first feature is right “beneath,” “below,” or “on bottom of” the second feature, and may also include an embodiment in which the first feature is not right “beneath,” “below,” or “on bottom of” the second feature, or just means that the first feature is at a height lower than that of the second feature.

In the following, a pedestal, a tray, a process chamber, a method for controlling a pedestal in a process chamber, and a method for manufacturing a tray in a process chamber according to embodiments of the present disclosure will be described in detail with reference to the drawings.

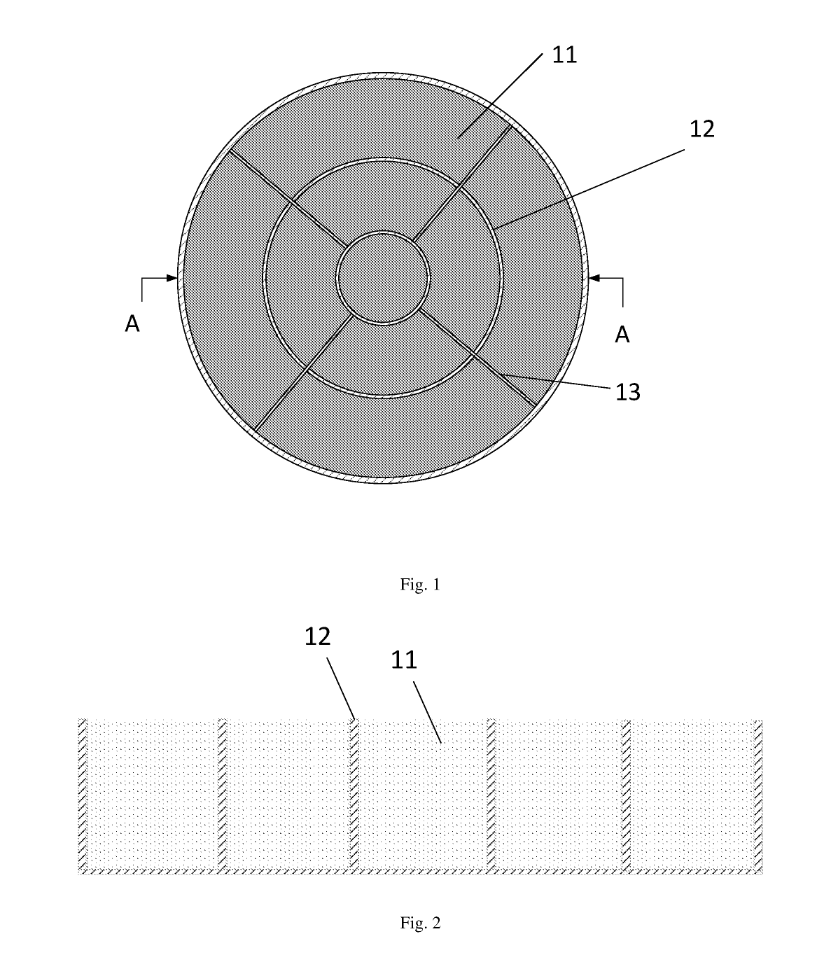

FIG. 1 is a schematic top view of a pedestal according to an embodiment of the present disclosure, and FIG. 2 is a sectional view of the pedestal along line A-A in FIG. 1.

As shown in FIG. 1 and FIG. 2, the pedestal comprises a plurality of subbases 11, a barrier 12 and a control device (not shown in FIG. 1 and FIG. 2).

Specifically, in the multi-physics coupling process, the pedestal is heated to produce a temperature field, thereby forming a temperature distribution; and/or the pedestal is an electrode to generate a radio frequency electromagnetic field, thereby forming a power distribution. Therefore, the plurality of subbases 11 can be made of a thermally conductive and electrically conductive material.

The barrier 12 defines a plurality of areas. The plurality of subbases 11 are disposed in the plurality of areas respectively. Therefore, the plurality of subbases 11 are independent from each other, and are electrically insulated and thermally insulated from each other.

The barrier 12 can be made of an electrically insulating and thermally insulating material. The barrier 12 can reduce the thermal diffusion effect and/or the conductivity between the plurality of subbases 11.

The control device is configured for controlling a temperature and/or a power of each subbase 11.

In one embodiment, the plurality of subbases 11 can be spliced as a whole by the barrier 12 to form the pedestal, and the pedestal has a round shape.

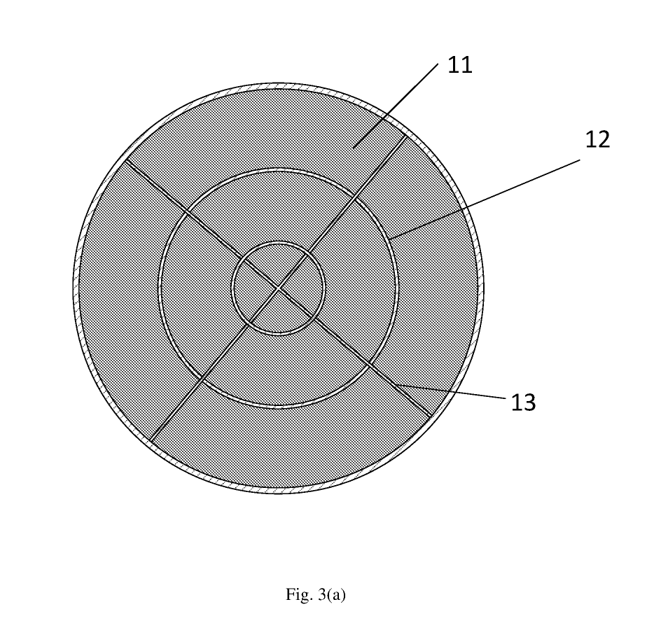

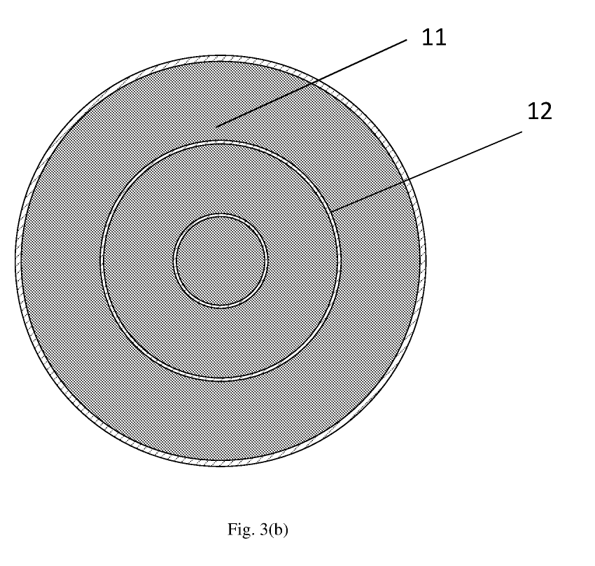

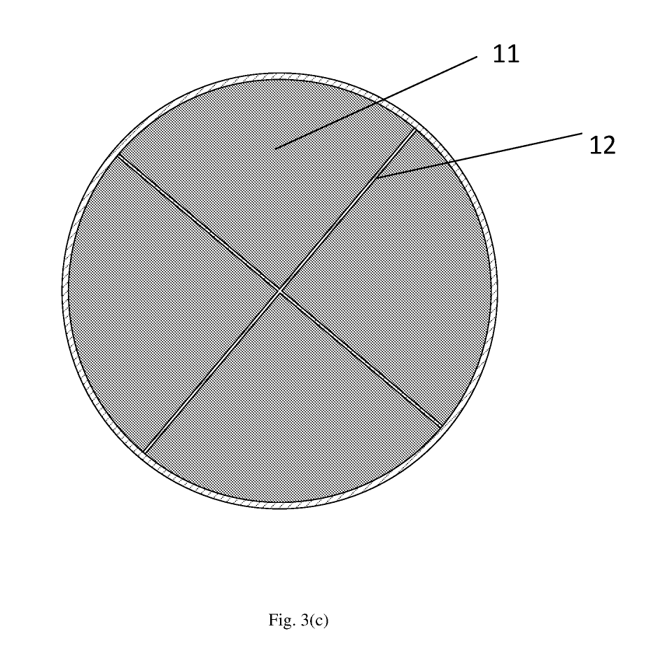

In one embodiment, each subbase 11 has an annular shape, a round shape, a sectorial shape or a sectorial annular shape. Specifically, as shown in FIG. 1, the plurality of subbases 11 can be spliced as a whole, meanwhile, the subbases 11 can have a sectorial annular shape or a round shape. FIG. 3(a) is a schematic top view of a pedestal according to an embodiment of the present disclosure. As shown in FIG. 3(a), the subbases 11 can have a sectorial shape or a sectorial annular shape. FIG. 3(b) is a schematic top view of a pedestal according to an embodiment of the present disclosure. As shown in FIG. 3(b), the subbases 11 can have an annular shape or a round shape and have different surface areas. FIG. 3(c) is a schematic top view of a pedestal according to an embodiment of the present disclosure. As shown in FIG. 3(c), the subbases 11 can have a sectorial shape and have the same surface area.

It should be understood that the pedestal is an immovable stage in a process chamber for carrying wafers, trays, etc. In the actual design, the subbases 11 can have different shapes according to the process requirement. Therefore, those of ordinary skill in the art can easily design other shapes of subbases 11 according to embodiments of the present invention.

It should also be understood that the pedestal spliced by the plurality of subbases 11 may have other shapes, e.g., rectangular shape, etc. In this case, the plurality of subbases 11 may be arranged in an array. Therefore, those of ordinary skill in the art can also easily design other shapes of bases.

With the pedestal according to an embodiment of the present disclosure, the plurality of subbases are independent from each other and are electrically insulated and thermally insulated from each other, so the subbases can be controlled independently. Therefore, it is possible to easily achieve the fine control on the spatial distributions (for example, the temperature distribution, the power distribution, etc.) of various physical fields (e.g., temperature fields or electromagnetic fields).

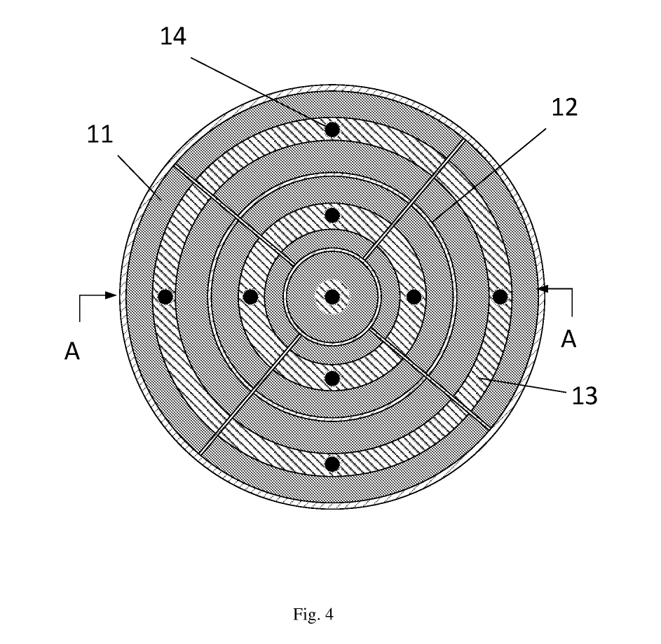

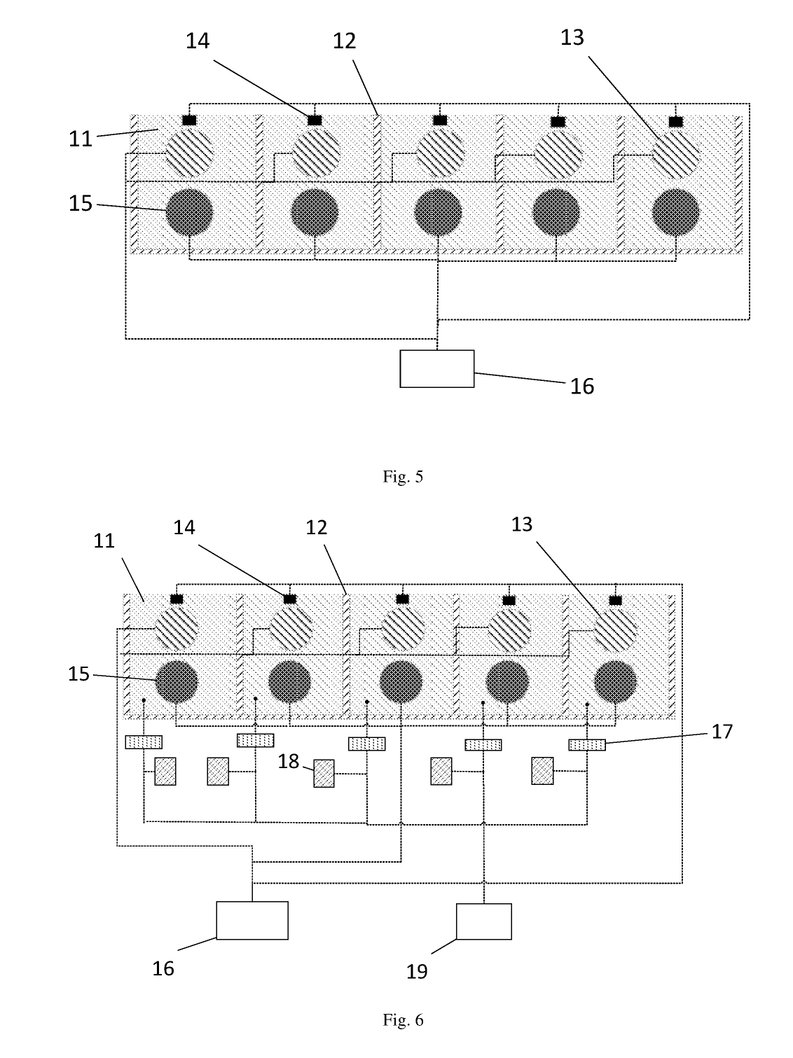

FIG. 4 is a schematic top view of a pedestal according to another embodiment of the present disclosure, and FIG. 5 is a sectional view of the pedestal along line A-A in FIG. 4.

As shown in FIG. 4 and FIG. 5, in one embodiment, the control device comprises a plurality of temperature control modules (not shown in FIG. 4 and FIG. 5) and a temperature controller 16. The plurality of temperature control modules are corresponding to the plurality of subbases 11 respectively, and the temperature controller 16 is connected with the plurality of temperature control modules respectively.

In one embodiment, each temperature control module comprises a heating rod 13, a temperature sensor 14 and a cooling unit 15.

Specifically, the heating rod 13, the temperature sensor 14 and the cooling unit 15 are disposed within the subbase 11 corresponding to the each temperature control module. The cooling unit 15 is disposed below the heating rod 13. The temperature controller 16 is connected with the heating rod 13, the temperature sensor 14 and the cooling unit 15 of the each temperature control module respectively. The temperature controller 16 is configured for obtaining the temperature of the subbase 11 by the temperature sensor 14, heating the subbase 11 by the heating rod 13, and cooling the subbase 11 by the cooling unit 15.

Therefore, each subbase 11 is corresponding to one individual temperature control module, and each temperature control module comprises a separate heating rod 13, a separate temperature sensor 14 and a separate cooling unit 15. Therefore, the temperature of the subbases 11 can be obtained individually by the corresponding temperature sensors 14, the subbases 11 can be heated individually by the corresponding heating rods 13, and the subbases 11 can be cooled individually by the corresponding cooling units 15.

With the pedestal according to an embodiment of the present disclosure, each subbase is corresponding to one individual temperature control module, and each temperature control module comprises a separate heating rod, a separate temperature sensor and a separate cooling unit, so the temperature of the subbases can be obtained individually by the corresponding temperature sensors so as to obtain the temperature distribution of the temperature field of the pedestal, the subbases can be heated individually by the corresponding heating rods, and the subbases can be cooled individually by the corresponding cooling units. Therefore, it is possible to easily achieve the fine control on the temperature distribution of the temperature field of the pedestal.

In one embodiment, the plurality of the heating rods 13 and/or the plurality of the temperature sensors 14 can be arranged annularly.

Specifically, if the pedestal has a round shape, the plurality of the heating rods 13 can be arranged annularly. The section of the heating rod 13 has a round shape (as shown in FIG. 5), however, the section of the heating rod 13 may have other shapes.

Specifically, the plurality of the temperature sensors 14 can be arranged in an annulus; each annulus can be provided with a plurality of temperature sensors 14, for example, four or more temperature sensors 14. The temperature sensor 14 may be a thermocouple sensor or other types of sensors. The temperature distribution of the temperature field can be obtained by the plurality of the temperature sensors 14.

FIG. 6 is a sectional view of a pedestal according to an embodiment of the present disclosure.

As shown in FIG. 6, in one embodiment, the control device comprises a plurality of power control modules (not shown in FIG. 6) and a power controller 19. The plurality of power control modules are corresponding to the plurality of subbases 11 respectively, and the power controller 16 is connected with the plurality of power control modules.

In one embodiment, each power control module comprises an adjustable resistor and/or capacitor 17 and an impedance detection unit 18.

Specifically, the adjustable resistor and/or capacitor 17 is connected with the subbase 11 corresponding to the each power control module, so the adjustable resistor and/or capacitor 17 and the corresponding subbase 11 form a loop. The impedance detection unit 18 is connected with the adjustable resistor and/or capacitor 17. The power controller 19 is connected with the adjustable resistor and/or capacitor 17 and the impedance detection unit 18 of the each power control module respectively; and the power controller 19 is configured for obtaining the power of the subbase 11 by the impedance detection unit 18 and controlling the power of the subbase 11 by the adjustable resistor and/or capacitor 17.

Therefore, each subbase 11 is corresponding to one individual power control module, and each power control module comprises a separate adjustable resistor and/or capacitor 17 and a separate impedance detection unit 18. The power of the subbases 11 can be obtained individually by the corresponding impedance detection units 18, and the power of the subbases 11 can be controlled individually by the corresponding adjustable resistors and/or capacitors 17.

In one embodiment, the heating rod 13, the temperature sensor 14 and the cooling unit 15 in each subbase 11 are optional.

With the pedestal according to an embodiment of the present disclosure, each subbase is corresponding to one individual power control module, and each power control module comprises a separate adjustable resistor and/or capacitor and a separate impedance detection unit, so the power of the subbases can be obtained individually by the corresponding impedance detection units so as to obtain the power distribution of the electromagnetic field of the pedestal, and the power of the subbases can be controlled individually by the corresponding adjustable resistors and/or capacitors. Therefore, it is possible to easily achieve the fine control on the power distribution of the electromagnetic field of the pedestal.

In order to better describe the pedestal according to an embodiment of the present disclosure, the application field of the pedestal will be described as follows.

PECVD (Plasma Enhanced Chemical Vapor Deposition) process is a typical multi-physics coupling process, in which the physical fields mainly consist of flow and thermal fields, electromagnetic fields and plasmas. However, for the process chamber for the PECVD process, it is possible to only regulate the average of temperature fields, electromagnetic fields and plasmas, but it is difficult to regulate the spatial distributions of temperature fields, electromagnetic fields and plasmas. Therefore, it is difficult to achieve the flexible regulation of the spatial distribution of the thin-film deposition. When the quality deviation of the thin film appears, the process chamber can be controlled to change relative process factors simply and rigidly, so the improvement in the process quality is very limited. Especially, with the increase in the wafer dimension and the scaling down of the critical dimension in the IC (Integrated Circuit) manufacturing process, the requirement for the consistency in the large-area thin-film deposition process is higher and higher. Therefore, the existing process chamber for the PECVD process cannot meet the requirement of the process quality.

Furthermore, the existing process chamber also has a problem in design: the process quality is guaranteed by the simple structure and rough control conditions, so the process chamber has the poor adaptability for different process requirements and the poor ability to regulate process deviations, even does not have the programmability in space. Therefore, it is necessary to redesign the device, thus causing high cost and low efficiency.

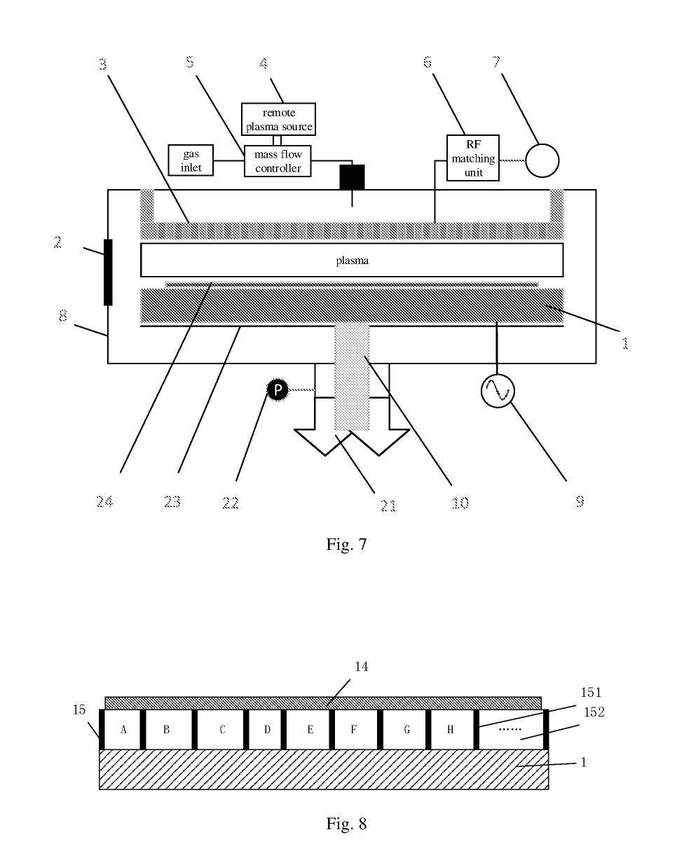

FIG. 7 is a schematic diagram of a process chamber for a PECVD process according to an embodiment of the present disclosure.

As shown in FIG. 7, the process chamber comprises: a pedestal 1, a chamber body 8, a chamber door 2, a spraying head 3, a remote plasma source 4, a mass flow controller 5, a RF (Radio Frequency) matching unit 6, a high frequency source 7, a low frequency source 9, an adjustment pillar 10, a vacuum pump 21, a pressure gauge 22, a thimble plate 23 and a substrate 24.

Specifically, when the chamber door 2 is closed, the interior of the chamber body 8 is isolated from the environment to achieve a vacuum seal. The remote plasma source 4 generates etching plasmas to clean deposits on the inner wall of the chamber body 8. The mass flow controller 5 controls the flow of the reactive gas into the chamber body 8, and the spraying head 3 controls the uniformity of the airflow. The high frequency source 7 and the low frequency source 9 generate an RF electromagnetic field within the chamber body 8 to dissociate the reactive gas so as to generate plasmas, and the RF matching unit 6 regulates the impedance characteristics of the RF circuit including plasmas to ensure that as much radio power as possible is injected into the chamber body 8. The adjustment pillar 10 regulates the electrode spacing when the RF capacitor discharges. The thimble plate 23 can lift or drop the substrate 24, which is mainly used for placing the substrate 24 into the chamber body 8 or taking the substrate 24 out of the chamber body 8. The vacuum pump 21 and the pressure gauge 22 may adjust the vacuum degree in the chamber body 8. The substrate 24 is placed on the pedestal 1, and a thin film is deposited on the substrate 24. The pedestal 1 may be any one described in the above embodiments. The pedestal 1 is used as a lower electrode of the RF circuit to heat the substrate 24. Therefore, the temperature of the substrate 24 may be adjusted.

Since the process chamber for the PECVD process comprises the pedestal according to embodiments of the present disclosure, the fine control on the temperature distribution and the power distribution may be achieved by means of a plurality of subbases electrically insulated and thermally insulated from each other, so as to achieve the flexible and fine control on the spatial distribution of process factors to achieve the fine control on the process objective.

It should also be understood that the process chamber for the PECVD process is only an example of the use of the pedestal. The pedestal according to any above embodiments can be used in other process chambers which have a similar function.

FIG. 8 is a schematic sectional view of a tray according to an embodiment of the present disclosure.

As shown in FIG. 8, the tray comprises a plurality of subbases 151 and a barrier 152.

Specifically, the barrier 152 defines a plurality of areas, in which the plurality of areas are electrically insulated and thermally insulated from each other.

The plurality of subbases 151 are disposed in the plurality of areas respectively, in which the plurality of subbases 151 are made of a medium. The plurality of subbases 151 are electrically insulated and thermally insulated from each other.

In one embodiment, medium parameters of the plurality of subbases 151 are not identical.

In one embodiment, each subbase 151 has an annular shape, a round shape, a sectorial shape or a sectorial annular shape.

The tray is placed on the pedestal according to any above embodiments, so as to finely control the power and/or temperature distribution. Therefore, the barrier 152 is similar to the barrier 12 according to any above embodiments, and the plurality of subbases 151 are similar to the plurality of subbases 11 according to any above embodiments. The arrangement of the barrier 152 and the plurality of subbases 151 are not repeated here.

It should be understood that the arrangement of the plurality of subbases 151 and the barrier 152 is not limited to that shown in FIG. 8. The barrier 152 is designed according to the dimension direction of the physical field distribution to be adjusted. For example, in the round field area, if the dimension direction of the physical field distribution is radial, the barrier 152 is designed as an annular array; if the dimension direction of the physical field distribution is radial and axial, the barrier 152 is designed as a rectangular array.

More specifically, in the tray, the filling material in the plurality of subbases 151 can be changed, so that the impedance of the tray spliced by the plurality of subbases 151 has a graded distribution in the normal plane. Therefore, the energy through the tray also has a graded distribution in the normal plane, so it is possible to adjust the temperature and/or power distribution.

The plurality of subbases 151 can be cylindrical; the filling material can be a gas or other materials which can be selected according to the requirement of the energy distribution obtained by the simulation. There is a relatively inexpensive way: to adjust the proportion of two materials with different impedance parameters in the plurality of subbases 151 to achieve the impedance adjustment of the plurality of subbases 151.

The mutual influence of adjacent subbases 151 may be reduced by means of the barrier 152, the energy through the subbases 151 may be adjusted separately.

More specifically, the tray is placed between the wafer and the pedestal, so it is fixed and is not controllable. Its principle of adjusting the temperature and/or power distribution is as follows:

by filling materials with different impedance parameters in the plurality of subbases 151 to achieve different distribution of energy through the subbases 151, so as to achieve the fine adjustment of the temperature and/or power distribution. If it is necessary to readjust the temperature and/or power distribution, the tray needs to be replaced. If it is necessary to adjust the temperature distribution, then a thermal impedance medium is filled in the subbases 151 according to a preset gradient. If it is necessary to adjust the power distribution, then an electrical impedance medium is filled in the subbases 151 according to a preset gradient.

With the tray according to an embodiment of the present disclosure, the tray can be placed on the pedestal to enable the energy through the tray to have a graded distribution in the normal plane, so it is possible to achieve the fine control on the spatial distributions (for example, the temperature distribution, the power distribution, etc.) of the process factors; and the tray also has a cheap, efficient, replaceable feature.

In order to achieve any above embodiments, a process chamber is provided according to an aspect of the present disclosure.

In some embodiments, the process chamber comprises a chamber body, a pedestal according to any above embodiments, in which the pedestal is received within the chamber body.

With the process chamber according to an embodiment of the present disclosure, it is possible to achieve the fine control on the spatial distributions (for example, the temperature distribution, the power distribution, etc.) of the process factors (e.g., the temperature field, the power field, etc.) by means of the pedestal.

In some embodiments, the process chamber also comprises a tray according to any above embodiments, in which the tray is disposed above the pedestal.

With the process chamber according to an embodiment of the present disclosure, it is possible to achieve the fine control on the spatial distributions (for example, the temperature distribution, the power distribution, etc.) of the process factors (e.g., the temperature field, the power field, etc.) by means of the pedestal and the tray.

In order to achieve any above embodiments, a process chamber is provided according to another aspect of the present disclosure.

In some embodiments, the process chamber comprises a chamber body, a pedestal received within the chamber body, and a tray according to any above embodiments, in which the tray is disposed above the pedestal.

With the process chamber according to an embodiment of the present disclosure, it is possible to achieve the fine control on the spatial distributions (for example, the temperature distribution, the power distribution, etc.) of the process factors (e.g., the temperature field, the power field, etc.) by means of the tray. Moreover, the tray can be replaced.

In order to achieve any above embodiments, a method for controlling a pedestal in a process chamber is provided according to an aspect of the present disclosure.

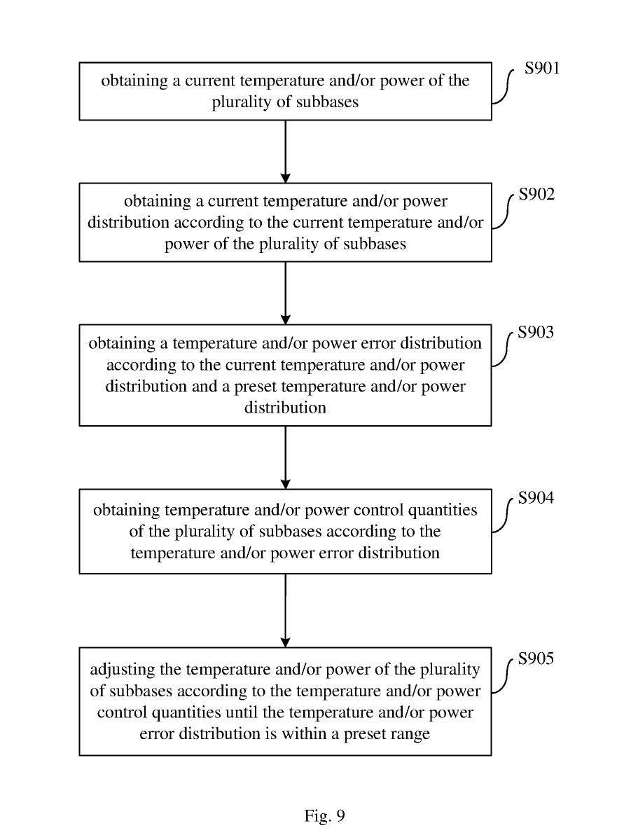

FIG. 9 is a flow chart of a method for controlling a pedestal in a process chamber according to an embodiment of the present disclosure.

As shown in FIG. 9, the process chamber comprises a pedestal according to any above embodiments, and the method comprises the following steps.

S901, a current temperature and/or power of the plurality of subbases is obtained.

S902, a current temperature and/or power distribution is obtained according to the current temperature and/or power of the plurality of subbases.

S903, a temperature and/or power error distribution is obtained according to the current temperature and/or power distribution and a preset temperature and/or power distribution.

S904, temperature and/or power control quantities of the plurality of subbases are obtained according to the temperature and/or power error distribution.

S905, the temperature and/or power of the plurality of subbases is adjusted according to the temperature and/or power control quantities until the temperature and/or power error distribution is within a preset range.

In order to achieve any above embodiments, a method for manufacturing a tray in a process chamber is provided according to an aspect of the present disclosure.

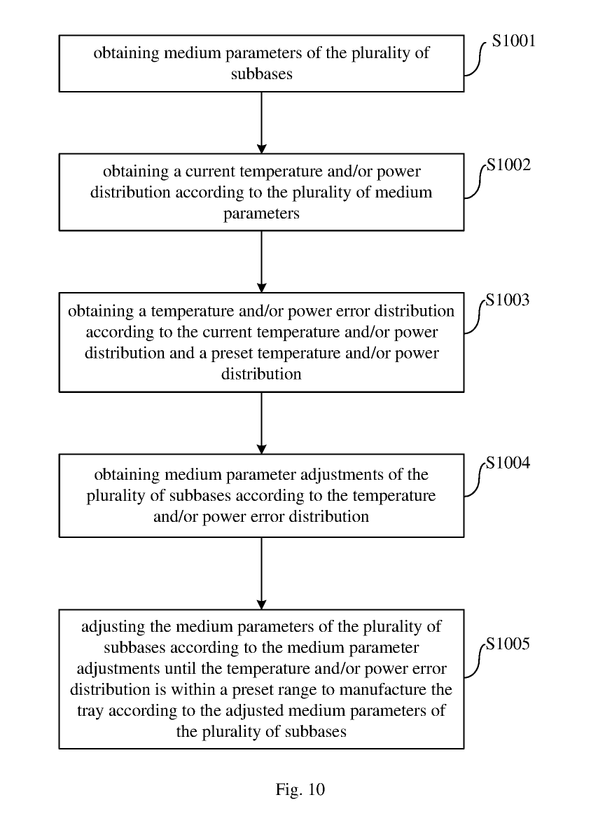

FIG. 10 is a flow chart of a method for manufacturing a tray in a process chamber according to an embodiment of the present disclosure.

As shown in FIG. 10, the process chamber comprises a tray according to any above embodiments, and the method comprises the following steps.

S1001, medium parameters of the plurality of subbases are obtained.

S1002, a current temperature and/or power distribution is obtained according to the plurality of medium parameters.

S1003, a temperature and/or power error distribution is obtained according to the current temperature and/or power distribution and a preset temperature and/or power distribution.

S1004, medium parameter adjustments of the plurality of subbases are obtained according to the temperature and/or power error distribution.

S1005, the medium parameters of the plurality of subbases are adjusted according to the medium parameter adjustments until the temperature and/or power error distribution is within a preset range to manufacture the tray according to the adjusted medium parameters of the plurality of subbases.

Any process or method described in the flowing diagram or other means may be understood as a module, segment or portion including one or more executable instruction codes of the procedures configured to achieve a certain logic function or process, and the preferred embodiments of the present disclosure include other performances, in which the performance may be achieved in other orders instead of the order shown or discussed, such as in a almost simultaneous way or in an opposite order, which should be appreciated by those having ordinary skills in the art to which embodiments of the present disclosure belong.

The logic and/or procedures indicated in the flowing diagram or described in other means herein, such as a constant sequence table of the executable code for performing a logical function, may be implemented in any computer readable storage medium so as to be adopted by the code execution system, the device or the equipment (such a system based on the computer, a system including a processor or other systems fetching codes from the code execution system, the device and the equipment , and executing the codes) or to be combined with the code execution system, the device or the equipment to be used. With respect to the description of the present invention, “the computer readable storage medium” may include any device including, storing, communicating, propagating or transmitting program so as to be used by the code execution system, the device and the equipment or to be combined with the code execution system, the device or the equipment to be used. The computer readable medium includes specific examples (a non-exhaustive list): the connecting portion (electronic device) having one or more arrangements of wire, the portable computer disc cartridge (a magnetic device), the random access memory (RAM), the read only memory (ROM), the electrically programmable read only memory (EPROMM or the flash memory), the optical fiber device and the compact disk read only memory (CDROM). In addition, the computer readable storage medium even may be papers or other proper medium printed with program, as the papers or the proper medium may be optically scanned, then edited, interpreted or treated in other ways if necessary to obtain the program electronically which may be stored in the computer memory.

It should be understood that, each part of the present invention may be implemented by the hardware, software, firmware or the combination thereof. In the above embodiments of the present invention, the plurality of procedures or methods may be implemented by the software or hardware stored in the computer memory and executed by the proper code execution system. For example, if the plurality of procedures or methods is to be implemented by the hardware, like in another embodiment of the present invention, any one of the following known technologies or the combination thereof may be used, such as discrete logic circuits having logic gates for implementing various logic functions upon an application of one or more data signals, application specific integrated circuits having appropriate logic gates, programmable gate arrays (PGA), field programmable gate arrays (FPGA).

It can be understood by those having the ordinary skills in the related art that all or part of the steps in the method of the above embodiments can be implemented by instructing related hardware via programs, the program may be stored in a computer readable storage medium, and the program includes one step or combinations of the steps of the method when the program is executed.

In addition, each functional unit in the present disclosure may be integrated in one progressing module, or each functional unit exists as an independent unit, or two or more functional units may be integrated in one module. The integrated module can be embodied in hardware, or software. If the integrated module is embodied in software and sold or used as an independent product, it can be stored in the computer readable storage medium.

The computer readable storage medium may be, but is not limited to, read-only memories, magnetic disks, or optical disks.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

1. A pedestal, comprising:
a barrier, defining a plurality of areas, wherein the plurality of areas are electrically insulated and thermally insulated from each other;
a plurality of subbases, disposed in the plurality of areas respectively;
a control device, configured for controlling a temperature and/or a power of each subbase.

2. The pedestal according to claim 1, wherein the control device comprises:
a plurality of temperature control modules corresponding to the plurality of subbases respectively; and
a temperature controller, connected with the plurality of temperature control modules respectively.

3. The pedestal according to claim 2, wherein each temperature control module comprises:
a heating rod;
a temperature sensor; and
a cooling unit, wherein the heating rod, the temperature sensor and the cooling unit are disposed within the subbase corresponding to the each temperature control module, the cooling unit is disposed below the heating rod;
wherein the temperature controller is connected with the heating rod, the temperature sensor and the cooling unit of the each temperature control module respectively, and the temperature controller is configured for obtaining the temperature of the subbase by the temperature sensor, heating the subbase by the heating rod, and cooling the subbase by the cooling unit.

4. The pedestal according to claim 1, wherein the control device comprises:
a plurality of power control modules corresponding to the plurality of subbases respectively; and
a power controller, connected with the plurality of power control modules respectively.

5. The pedestal according to claim 4, wherein each power control module comprises:
an adjustable resistor and/or capacitor, connected with the subbase corresponding to the each power control module, and
an impedance detection unit, connected with the adjustable resistor and/or capacitor;
wherein the power controller is connected with the adjustable resistor and/or capacitor and the impedance detection unit of the each power control module respectively, and the power controller is configured for obtaining the power of the subbase by the impedance detection unit and controlling the power of the subbase by the adjustable resistor and/or capacitor.

6. The pedestal according to claim 1, wherein each subbase has an annular shape, a round shape, a sectorial shape or a sectorial annular shape.

7. A tray, comprising:
a barrier, defining a plurality of areas, wherein the plurality of areas are electrically insulated and thermally insulated from each other; and
a plurality of subbases, disposed in the plurality of areas respectively, wherein the plurality of subbases are made of a medium.

8. The tray according to claim 7, wherein medium parameters of the plurality of subbases are not identical.

9. The tray according to claim 7, wherein each subbase has an annular shape, a round shape, a sectorial shape or a sectorial annular shape.

10. A process chamber, comprising:
a chamber body;
a pedestal, wherein the pedestal is received within the chamber body and comprises:
a first barrier, defining a plurality of first areas, wherein the plurality of first areas are electrically insulated and thermally insulated from each other;
a plurality of first subbases, disposed in the plurality of first areas respectively;
a control device, configured for controlling a temperature and/or a power of each first subbase; and
a tray, wherein the tray is disposed above the pedestal and comprises:
a second barrier, defining a plurality of second areas, wherein the plurality of second areas are electrically insulated and thermally insulated from each other; and
a plurality of second subbases, disposed in the plurality of second areas respectively, wherein the plurality of second subbases are made of a medium.

11. (canceled)

12. (canceled)
